(19) United States
(12) Patent Application Publication
(10) Pub. No.: US 2002/0055230 A1
(43) Pub. Date: May 9, 2002

(54) Structure of NROM and fabricating method thereof

(76) Inventor: Kent Kuohua Chang, Taipei (TW)

Correspondence Address: J.C. Patents Inc., Suite 250, 4 Venture, Irvine, CA, 92618, US

(21) Appl. No.: 09/997,649

(22) Filed: Nov. 27, 2001

(30) Foreign Application Priority Data
Nov. 9, 2000 (TW) 90127833

(51) Int. Cl. H01L 21/336

(52) U.S. Cl. 438/258

(57) ABSTRACT

A method for fabricating a nitride read-only memory (NROM). A gate structure comprising an oxide/nitride/oxide composite layer and a gate conductive layer is formed on a substrate. A source/drain region is formed in the substrate beside the gate structure. A silicon oxide spacer is formed on the side-wall of the gate structure and then a silicon nitride spacer is formed on the side-wall of the silicon oxide spacer. The surface of the substrate is cleaned and a metal silicide layer is further formed on the source/drain region. Since the silicon nitride spacer is capable of protecting the silicon oxide spacer from thinning during the cleaning step, a junction leakage can be prevented. Meanwhile, the parasitic capacitance between the gate and the source/drain region is lower by adopting the silicon oxide spacer, so that the performance of the device can be improved.

### CROSS-REFERENCE TO RELATED APPLICATION

This application claims the priority benefit of Taiwan application serial no. 90127833, filed Nov. 9, 2001.

### BACKGROUND OF THE INVENTION

1. Field of Invention

The present invention relates to a structure of a non-volatile memory and a fabricating method thereof. More particularly, the present invention relates to a structure of a nitride read-only memory (NROM) and a fabricating method thereof.

2. Description of Related Art

The non-volatile memory includes the electrically erasable programmable read-only memory (EEPROM), which can be programmed, read, and erased for many times and can retain the data when the electrical power is turned off. Because of the above-mentioned advantages, the EEPROM is now in widely applied in personal computers and electronic apparatuses.

The conventional EEPROM comprises a floating gate and a control gate, which are formed from doped polysilicon. When the memory is being programmed, hot electrons are injected into the polysilicon floating gate and are distributed evenly in the entire floating gate. However, when there are defects in the tunnel oxide layer under the polysilicon floating gate, the electrons stored in the floating gate easily leak out so that the reliability of the memory device is lowered.

In order to prevent the leakage of an EEPROM device, a charge trapping layer such as a silicon nitride layer is used recently to replace the polysilicon floating gate. The charge trapping layer made from silicon nitride is usually sandwiched in between two silicon oxide layers to form an ONO composite layer. The ONO layer and a gate conductive layer disposed on the ONO layer construct a stacked gate structure, while the EEPROM with such a stacked gate structure is called a NROM (nitride read-only memory). When the memory device is programmed with the biases applied on the control gate and the source/drain region, hot electrons will be generated in the channel near the drain region and injected into the charge trapping layer. Since the silicon nitride is capable of trapping electrons, the injected electrons will be localized in the charge trapping layer, rather than distribute evenly in the entire charge trapping layer. Consequently, the charge trapping region is quite small and is thus located on less defects of the tunnel oxide layer. The leakage is thereby less in the memory device.

Another advantage of the NROM is that two bits can be saved in one NROM cell. This is achieved by applying a higher voltage on one of the two doped regions beside the stacked gate to make the hot electrons be injected into the silicon nitride layer near the selected doped region, and then doing the analogous thing to the other doped region. In other words, the silicon nitride layer of a single NROM cell can have two or one group(s) of electrons or zero electron stored in it, which means that one NROM cell can be programmed into one of the four states or that two bits can be stored in one NROM cell.

In the conventional fabricating process of a NROM, a silicon oxide spacer or a silicon nitride spacer is formed on the side-wall of the gate structure before the salicide (self-aligned silicide) process. However, when the silicon oxide is used as the material of the spacer, the spacer will be partly eroded during the cleaning step for removing the native oxide and impurities before the salicide process. Therefore, the metal silicide layer formed later is quite close to the source/drain extension, so that the junction leakage easily occurs. On the other hand, though a nitride spacer will not be damaged during the cleaning step, the higher dielectric constant of silicon nitride will induce a larger parasitic capacitance between the gate and the source/drain region, which in turn reduces the performance of the device.

### SUMMARY OF THE INVENTION

Accordingly, this invention provides a structure of a NROM and a method for fabricating the same in order to prevent the junction leakage and to decrease the parasitic capacitance between the gate and the source/drain region, so as to improve the performance of the device.

In the fabricating method of a NROM provided in this invention, a gate structure composed of an ONO composite dielectric layer and a gate conductive layer is formed on a substrate. A source/drain region is formed in the substrate beside the gate structure. A first spacer is formed on the side-wall of the gate structure and a second spacer is then formed on the side-wall of the first spacer. Thereafter, a cleaning step is performed to clean the surface of the substrate and a metal silicide layer is formed on the source/drain region after the cleaning step.

The structure of NROM provided in this invention comprises at least a substrate, a gate structure, a first spacer, a second spacer, a source/drain region, and a metal silicide layer. The gate structure is located on the substrate. The first spacer is disposed on the side-wall of the gate structure and the second spacer is disposed on the side-wall of the first spacer. The source/drain region is located in the substrate beside the gate structure and the metal silicide layer is disposed on the gate structure and the source/drain region.

In addition, the gate structure comprises a gate conductive layer and a composite dielectric layer between the gate conductive layer and the substrate, wherein the composite dielectric layer has an ONO structure. Further, the NROM structure of this invention may include a source/drain (S/D) extension under the first spacer and next to the source/drain region.

In this invention, the material of the first spacer can be silicon oxide and that of the second spacer can be silicon nitride. In such a situation, the nitride spacer is capable of protecting the oxide spacer from thinning during the cleaning step for removing the native oxide and thereby the metal silicide layer will not approach to the S/D extension to cause the junction leakage. Besides, the dielectric constant of the silicon oxide is smaller than that of the silicon nitride, so that the parasitic capacitance between the gate and the source/drain region can be decreased and the performance of the device can be improved. Moreover, the material of the first spacer is not limited to silicon oxide but can be a low-K material with a dielectric constant smaller than 4 or smaller than that of the silicon oxide to further decrease the parasitic capacitance between the gate and the source/drain region. On the other hand, the material of the second spacer is not limited to silicon nitride but can be the other materials having smaller etching rates than that of the first spacer and being capable of protecting the first spacer in the cleaning process.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A˜1D illustrate the process flow of fabricating a NROM in a cross-sectional view according to a preferred embodiment of this invention.

### DESCRIPTION OF THE PREFERRED EMBODIMENTS

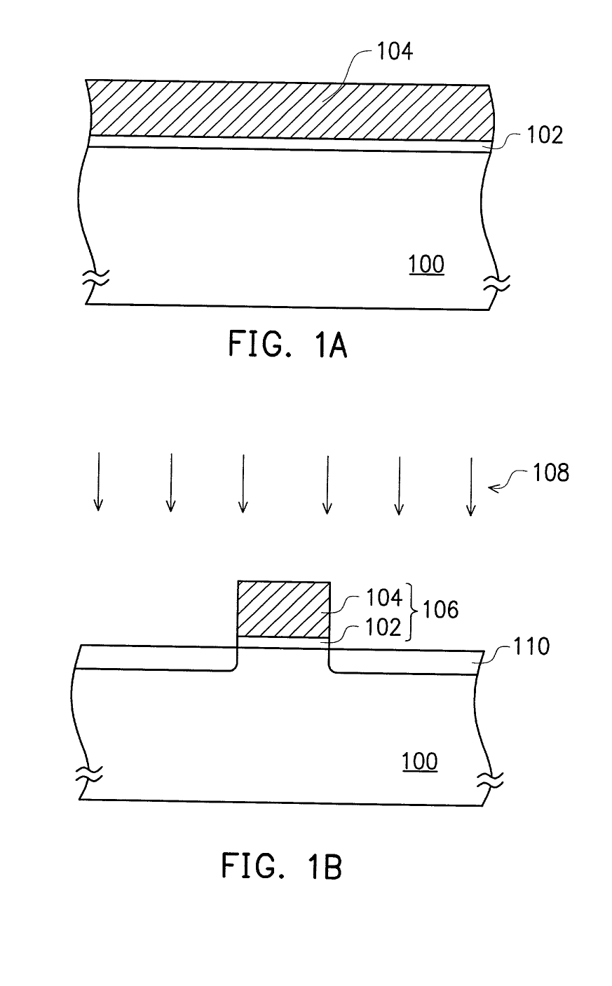

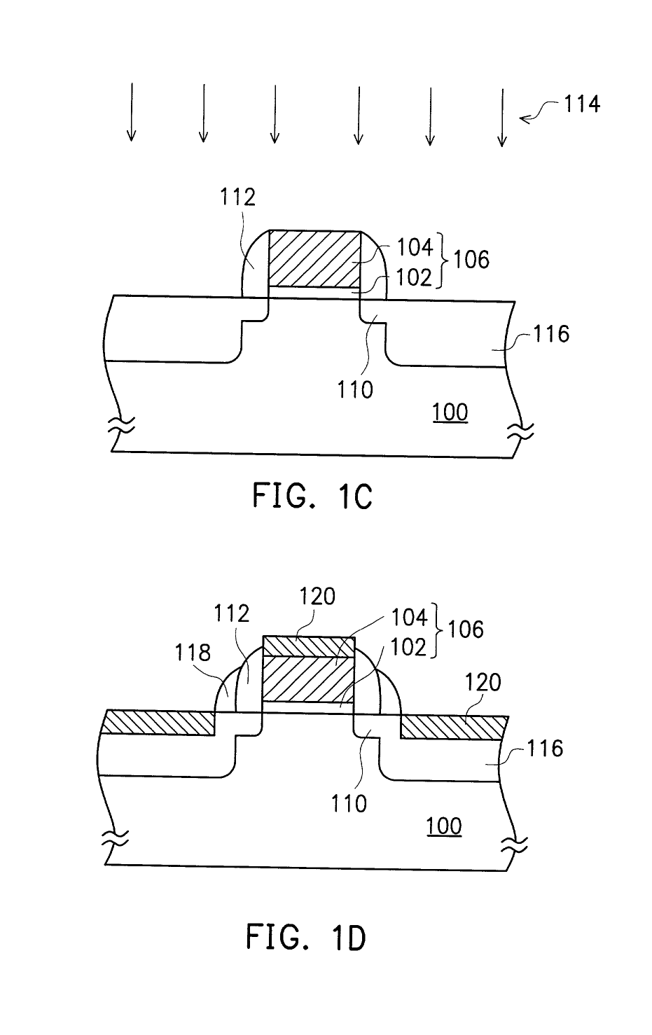

Refer to FIGS. 1A˜1D, which illustrate the process flow of fabricating a NROM in a cross-sectional view according to a preferred embodiment of this invention.

Refer to FIG. 1A, a substrate 100, such as a silicon substrate, is provided and then a composite dielectric layer 102 and a gate conductive layer 104 are sequentially formed on the substrate 100. The composite dielectric layer 102 has an ONO structure that comprises a tunnel oxide layer, a nitride charge-trapping layer, and another silicon oxide layer. The gate conductive layer 104 includes, for example, a doped polysilicon layer formed by a method such as chemical vapor deposition with in-situ doping.

Refer to FIG. 1B, the gate conductive layer 104 and the composite dielectric layer 102 are then patterned by using the lithography and etching techniques to form a gate structure 106.

Thereafter, an implantation 108 is conducted to form a lightly doped source/drain extension 110 in the substrate 100 beside the gate structure 106. For a P-type NROM, the implantation 108 is conducted with, for example, boron difluoride ions (BF₂⁺) with a kinetic energy of 20 KeV and a dosage of 4.5×10¹³/cm². For an N-type NROM, the implantation 108 is conducted with, for example, phosphorous ions (P⁺) with a kinetic energy of 35 KeV and a dosage of 4×10¹³/cm².

Refer to FIG. 1C, a spacer 112 is formed on the side-wall of the gate structure 106. The spacer 112 has a thickness of 600˜1000 Å and comprises the silicon oxide formed by chemical vapor deposition using TEOS (tetraethyl-ortho-silicate)/O₃ as the reaction gas. The steps for forming the spacer 112 includes depositing a conformal dielectric layer (not shown) on the substrate 100 and then removing a portion of the dielectric layer by performing an anisotropic etching step including a RIE (Reactive Ion Etching) step.

Still referring to FIG. 1C, by using the spacer 112 and the gate structure 106 as a mask, an implantation 114 is performed to form a source/drain region 116 in the substrate 100 beside the spacer 112 and the gate structure 106. For a P-type NROM, the implantation 114 is conducted with, for example, boron difluoride ions (BF₂⁺) with a kinetic energy of 40 KeV and a dosage of 2×10¹⁵/cm². For an N-type NROM, the implantation 114 is conducted with, for example, arsenic ions (As⁺) with an energy of 80 KeV and a dosage of 3×10¹⁵/cm².

Refer to FIG. 1D, another spacer 118 is formed on the side-wall of the spacer 112. The spacer 118 is formed from a material having a smaller etching rate than that of the material of the spacer 112 in the step of removing the native oxide, such as silicon nitride. The width of the spacer 118 does not exceed that of the spacer 112 and is, for example, 600 Å. The steps for forming the spacer 118 include depositing a conformal dielectric layer (not shown) on the substrate 100 and then removing a portion of the dielectric layer by performing an anisotropic etching step including a RIE (Reactive Ion Etching) step.

Thereafter, a cleaning step is performed to remove the native oxide and impurities on the surfaces of the substrate 100 and the gate structure 106. The cleaning step includes removing the native oxide on the surfaces of the substrate 100 and the gate structure 106 by ion bombardment and then washing the wafer by, for example, an ammonia-hydrogen peroxide mixture (APM) and/or a sulfuric acid-hydrogen peroxide mixture (SPM).

Thereafter, a conductive layer 120, such as a salicide (self-aligned silicide) layer formed by a salicide process, is formed on the top of the gate structure 106 and the source/drain region 116. The salicide process includes the following steps, for example. A refractory metal material such as titanium (Ti), tungsten (W), cobalt (Co), nickel (Ni), platinum (Pt), or palladium (Pb) is deposited over the entire wafer by magnetron DC (direct current) sputtering. A rapid thermal process is then performed to make the metal material react with the silicon on the top of the gate structure 106 and the source/drain region 116, so as to form a metal silicide layer thereon. After that, the metal material not reacted with the silicon is removed.

Though the silicon oxide is taken as an example of the material of the spacer 112 in this embodiment, the material of the spacer 112 can be another materials with a dielectric constants smaller than 4 or smaller than that of silicon oxide. Thus, the parasitic capacitance between the gate and the source/drain can be further decreased, so that the performance of the device can be improved. Such a low-K material is, for example, fluorinated silicate glass (FSG), organosilicate glass, parylene, fluorinated amorphous carbon (FLAC), or hydrogen silsesquioxane (HSQ). Besides, the material of the spacer 118 is not limited to silicon nitride. Silicon oxynitride (SiON), phosphosilicate glass (PSG), or borophosphosilicate glass (BPSG) that is not easily damaged during the cleaning step can also be used for the spacer 118.

Refer to FIG. 1D, FIG. 1D shows the structure of the NROM according to the preferred embodiment of this invention.

The NROM comprises the substrate 100, a gate structure 106 on the substrate 100, a silicon oxide spacer 112 on the side-wall of the gate structure 106, a silicon nitride 118 on the side-wall of the silicon oxide spacer 112, a source/drain region 116 in the substrate 100 beside the gate structure 106, and a conductive layer 120 on the gate structure 106 and the source/drain region 116. The gate structure 106 comprises a gate conductive layer 104 and a composite dielectric layer 102 between the gate conductive layer 104 and the substrate 100, wherein the composite dielectric layer 102 has an ONO structure. Moreover, there is a source/drain extension 110 under the silicon oxide spacer 112 and next to source/drain region 116.

According to the preferred embodiment of this invention, since a silicon nitride spacer is formed on the side-wall of the silicon oxide spacer, the silicon oxide spacer can be protected from thinning during the cleaning step for removing the native oxide. The metal silicide layer thereby will not be too close to the S/D extension to cause the junction leakage. Besides, since the dielectric constant of the silicon oxide is smaller than that of the silicon nitride, the parasitic capacitance between the gate and the source/drain region is decreased and the performance of the device is improved.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A method for fabricating a NROM, comprising the steps of:
providing a substrate;
forming a stacked gate structure on the substrate;
forming a source/drain region in the substrate beside the stacked gate structure;
forming a silicon oxide spacer on a side-wall of the stacked gate structure; and
forming a silicon nitride spacer on a side-wall of the silicon oxide spacer.

2. The method of claim 1, further comprising the steps of:
conducting a cleaning step to clean the substrate after the silicon nitride spacer is formed; and
forming a metal silicide layer on the source/drain region.

3. The method of claim 1, wherein a width of the silicon nitride spacer does not exceed that of the silicon oxide spacer.

4. The method of claim 1, wherein the stacked gate structure comprises a gate conductive layer and a composite dielectric layer.

5. The method of claim 4, wherein the composite dielectric layer includes an ONO (silicon oxide/silicon nitride/silicon oxide) structure.

6. A method for fabricating a NROM, comprising the steps of:
providing a substrate;
forming a composite dielectric layer on the substrate;
forming a gate conductive layer on the composite dielectric layer;
patterning the gate conductive layer and the composite dielectric layer to form a gate structure;
forming a source/drain extension in the substrate beside the gate structure;
forming a first spacer on a side-wall of the gate structure, wherein a material of the first spacer has a dielectric constant smaller than 4;
forming a source/drain region in the substrate beside the first spacer and the gate structure; and
forming a second spacer on a side-wall of the first spacer, wherein a material of the second spacer has an etching rate different from that of the first spacer.

7. The method of claim 6, further comprising the steps of:
conducting a cleaning step to clean the substrate after the second spacer is formed; and
forming a metal silicide layer on the source/drain region.

8. The method of claim 6, wherein a width of the second spacer does not exceed that of the first spacer.

9. The method of claim 6, wherein the composite dielectric layer comprises an ONO (silicon oxide/silicon nitride/silicon oxide) layer.

10. The method of claim 6, wherein the first spacer comprises silicon oxide.

11. The method of claim 6, wherein the second spacer comprises silicon nitride.

12. A structure of a NROM, comprising:
a substrate;
a stacked gate structure on the substrate;
a first spacer on a side-wall of the stacked gate structure;
a second spacer on a side-wall of the first spacer; and
a source/drain region in the substrate beside the stacked gate structure.

13. The structure of claim 12, wherein a material of the first spacer has a dielectric constant smaller than 4.

14. The structure of claim 12, wherein the first spacer comprises silicon oxide.

15. The structure of claim 12, wherein a material of the first spacer and a material of the second spacer have different etching rates.

16. The structure of claim 12, wherein the second spacer comprises silicon nitride.

17. The structure of claim 12, wherein the stacked gate structure comprises:
a gate conductive layer on the substrate; and
a composite dielectric layer between the gate conductive layer and the substrate.

18. The structure of claim 17, wherein the composite dielectric layer comprises an ONO (silicon oxide/silicon nitride/silicon oxide) structure.

19. The structure of claim 12, further comprising a source/drain extension under the first spacer and next to the source/drain region.

20. The structure of claim 12, further comprising a metal silicide layer on the stacked gate structure and the source/drain region beside the second spacer.
